(19) United States
(12) Patent Application Publication
(10) Pub. No.: US 2025/0175127 A1
(43) Pub. Date: May 29, 2025

(54) METHOD AND ELECTRONIC DEVICE FOR DIGITAL PRE-DISTORTION (DPD)

(71) Applicant: MEDIATEK INC., Hsinchu City (TW)

(72) Inventors: Ting-Hsun KUO, Hsinchu City (TW); Yu-Rong CHENG, Hsinchu City (TW); Cheng-Yu WU, Hsinchu City (TW)

(21) Appl. No.: 18/816,107

(22) Filed: Aug. 27, 2024

Related U.S. Application Data
(60) Provisional application No. 63/602,680, filed on Nov. 27, 2023.

(51) Int. Cl. H03F 1/32; H04B 1/04

(52) U.S. Cl. CPC H03F 1/3258; H03F 1/3247; H04B 1/0475

(57) ABSTRACT

A method for digital pre-distortion (DPD) is provided. The method includes the following steps. The DPD coefficient residual at the current time point is calculated. The DPD coefficient residual is associated with an input signal received by a DPD circuit and an output signal output by a power amplifier. The last DPD coefficient at the last time point is obtained. A convolution is performed between the DPD coefficient residual and the last DPD coefficient to obtain an intermediate coefficient. A truncation is performed on the intermediate coefficient to obtain a current DPD coefficient. DPD is performed based on the current DPD coefficient to compensate for the nonlinearity of the PA.

### CROSS REFERENCE TO RELATED APPLICATIONS

This Application claims priority of U.S. Provisional Patent Application No. 63/602,680, filed on Nov. 27, 2023, the entirety of which is incorporated by reference herein.

### BACKGROUND OF THE INVENTION

### Field of the Invention

The present invention relates to a method for digital pre-distortion (DPD), and, in particular, to a method and an electronic device for DPD using coefficient-based DPD combining.

### Description of the Related Art

Digital pre-distortion (DPD) is a promising technique to improve transmitting (TX) efficiency. In order to obtain a better Error Vector Magnitude (EVM) and Adjacent Channel Ratio (ACLR) at the output end of a power amplifier (PA) under certain PA settings, how to improve DPD performance has become an important issue.

### BRIEF SUMMARY OF THE INVENTION

An embodiment of the present invention provides a method for digital pre-distortion (DPD). The method is applied to an electronic device having a DPD circuit and a power amplifier (PA). The DPD circuit is electrically connected to the PA. The method includes the following steps. The DPD coefficient residual at the current time point is calculated. The DPD coefficient residual is associated with an input signal received by a DPD circuit and an output signal output by a power amplifier. The last DPD coefficient at the last time point is obtained. A convolution is performed between the DPD coefficient residual and the last DPD coefficient to obtain an intermediate coefficient. A truncation is performed on the intermediate coefficient to obtain a current DPD coefficient. DPD is performed based on the current DPD coefficient to compensate for the nonlinearity of the PA.

According to the method described above, the DPD coefficient residual and the last DPD coefficient are expressed as polynomial matrices.

According to the method described above, the DPD coefficient residual and the last DPD coefficient are expressed as lookup table (LUT) matrices.

The method further includes the following step. The DPD coefficient residual and the last DPD coefficient are converted from the form of polynomial matrices to the form of lookup table (LUT) matrices based on the amplitudes of the input signal and the output signal before performing the convolution

According to the method described above, the intermediate coefficient and the current DPD coefficient are expressed as LUT matrices.

According to the method described above, the polynomial matrices are converted to the LUT matrices by substituting the amplitudes of the input signal and the output signal into the polynomial matrices.

The method further includes the following step. The current DPD coefficient is converted from the form of a LUT matrix to the form of a polynomial matrix.

According to the method described above, the step of performing the truncation on the intermediate coefficient to obtain the current DPD coefficient includes the following steps. A Fast Fourier Transform (FFT) is performed on the intermediate coefficient. A least square fitting is performed to obtain the current DPD coefficient.

According to the method described above, the input signal and the output signal are In-phase Quadrature (IQ) signals.

According to the method described above, the computation cost of the LUT matrix is less than that of the polynomial matrix.

An embodiment of the present invention also provides an electronic device including a digital pre-distortion (DPD) circuit, a power amplifier (PA), and an estimation circuit. The DPD circuit receives an input signal. The PA is electrically connected to the DPD circuit and outputs an output signal. The estimation circuit is electrically connected to the DPD circuit and the PA. The estimation circuit calculates the DPD coefficient residual at the current time point. The DPD coefficient residual is associated with the input signal received by the DPD circuit and the output signal output by the PA. The estimation circuit obtains the last DPD coefficient at the last time point, performs a convolution between the DPD coefficient residual and the last DPD coefficient to obtain an intermediate coefficient, and perform a truncation on the intermediate coefficient to obtain a current DPD coefficient. The DPD circuit performs DPD based on the current DPD coefficient to compensate for the nonlinearity of the PA.

According to the electronic device described above, the DPD coefficient residual and the last DPD coefficient are expressed as polynomial matrices.

According to the electronic device described above, the DPD coefficient residual and the last DPD coefficient are expressed as lookup table (LUT) matrices.

According to the electronic device described above, the estimation circuit converts the DPD coefficient residual and the last DPD coefficient from the form of polynomial matrices to the form of lookup table (LUT) matrices based on the amplitudes of the input signal and the output signal before performing the convolution.

According to the electronic device described above, the intermediate coefficient and the current DPD coefficient are expressed as LUT matrices.

According to the electronic device described above, the polynomial matrices are converted to the LUT matrices by substituting the amplitudes of the input signal and the output signal into the polynomial matrices.

According to the electronic device described above, the estimation circuit converts the current DPD coefficient from the form of a LUT matrix to the form of a polynomial matrix.

According to the electronic device described above, the estimation circuit performs a Fast Fourier Transform (FFT) on the intermediate coefficient, and performs least square fitting on the intermediate coefficient to obtain the current DPD coefficient

According to the electronic device described above, the input signal and the output signal are In-phase Quadrature (IQ) signals.

According to the electronic device described above, computation cost of the LUT matrix is less than that of the polynomial matrix.

### BRIEF DESCRIPTION OF THE DRAWINGS

The present invention can be more fully understood by reading the subsequent detailed description and examples with references made to the accompanying drawings, wherein:

FIG. 1 shows a flow chart of a method for digital pre-distortion (DPD) in accordance with some embodiments of the present invention;

FIG. 2 shows a detail flow chart of step S106 in FIG. 1 in accordance with some embodiments of the present invention;

FIG. 3 shows a schematic diagram of an electronic device 300 in accordance with some embodiments of the present invention;

FIG. 4 shows a detail flow chart of operations of an estimation circuit 400 in the prior art;

FIG. 5 shows a detail flow chart of operations of an estimation circuit 306 in FIG. 3 in accordance with some embodiments of the present invention; and

FIG. 6 shows a detail flow chart of operations of the estimation circuit 306 in FIG. 3 in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present invention are used to indicate the existence of specific technical features, values, method steps, operations, units and/or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present invention. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the present invention.

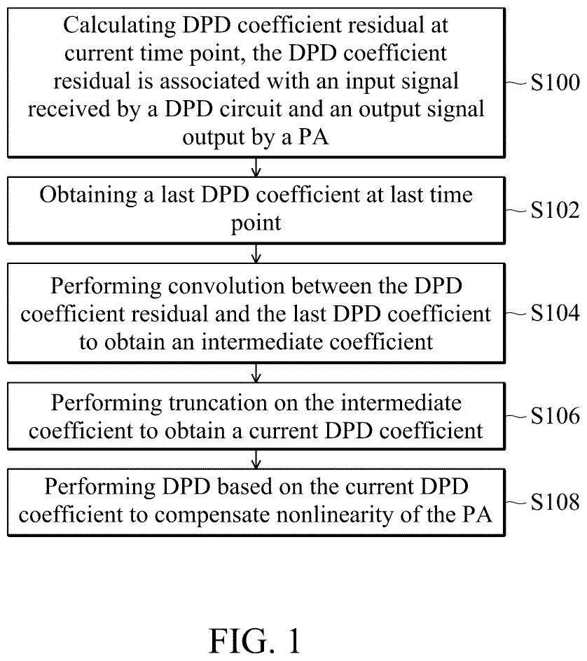

FIG. 1 shows a flow chart of a method for digital pre-distortion (DPD) in accordance with some embodiments of the present invention. The method for DPD of the present invention is applied to an electronic device having a DPD circuit and a power amplifier (PA). In some embodiments, the electronic device may be a transmitter, but the present invention is not limited thereto. The method for DPD of the present invention includes the following steps. The DPD coefficient residual at the current time point is calculated. The DPD coefficient residual is associated with an input signal received by the DPD circuit and an output signal output by the power amplifier (step S100). The last DPD coefficient at the last time point is obtained (step S102). A convolution is performed between the DPD coefficient residual and the last DPD coefficient to obtain an intermediate coefficient (step S104). A truncation is performed on the intermediate coefficient to obtain a current DPD coefficient (step S106). DPD is performed based on the current DPD coefficient to compensate for the nonlinearity of the PA (step S108).

In some embodiments, the DPD coefficient residual in step S100 and the last DPD coefficient in step S102 may be expressed as polynomial matrices. In some embodiments, the DPD coefficient residual in step S100 and the last DPD coefficient in step S102 may be expressed as lookup table matrices. In some embodiments, when the DPD coefficient residual in step S100 and the last DPD coefficient in step S102 are expressed as the polynomial matrices, the method for DPD of the present invention further includes the following steps. The DPD coefficient residual and the last DPD coefficient are converted from the form of polynomial matrices to the form of lookup table (LUT) matrices based on the amplitudes of the input signal and the output signal before performing step S104 in FIG. 1.

In some embodiments, when the DPD coefficient residual in step S100 and the last DPD coefficient in step S102 are expressed as the polynomial matrices, the method for DPD of the present invention further includes the following step. The current DPD coefficient is converted from the form of a LUT matrix to the form of a polynomial matrix after performing step S106 in FIG. 1. In some embodiments, computation cost of the LUT matrix is less than that of the polynomial matrix. In some embodiments, the input signal and the output signal in step S100 are In-phase Quadrature (IQ) signals, but the present invention is not limited thereto.

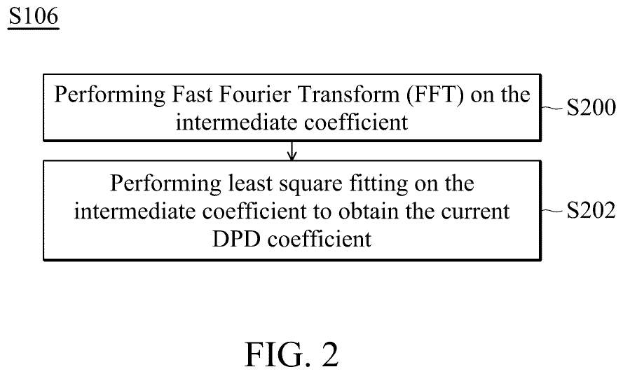

FIG. 2 shows a detail flow chart of step S106 in FIG. 1 in accordance with some embodiments of the present invention. As shown in FIG. 2, step S106 in FIG. 1 includes the following steps. A Fast Fourier Transform (FFT) is performed on the intermediate coefficient (step S200). Least square fitting is performed on the intermediate coefficient to obtain the current DPD coefficient (step S202). That is, the current DPD coefficient is determined based on the DPD coefficient residual in step S100 and the last DPD coefficient in step S102.

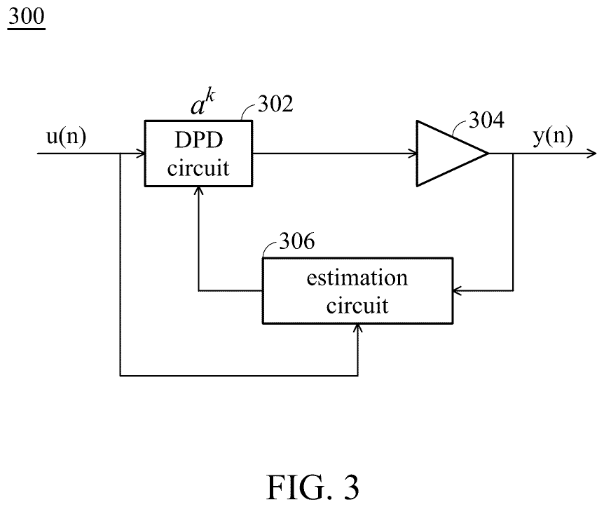

FIG. 3 shows a schematic diagram of an electronic device 300 in accordance with some embodiments of the present invention. As shown in FIG. 3, the electronic device 300 may be a transmitter in a laptop, a tablet, a smartphone, or a smart watch, but the present invention is not limited thereto. As shown in FIG. 3, the electronic device 300 includes a digital pre-distortion (DPD) circuit 302, a power amplifier (PA) 304, and an estimation circuit 306. In some embodiments, operations performed by the DPD circuit 302 may be completed by hardware, for example, a digital signal processor. In some embodiments, operations performed by the estimation circuit 304 may be completed by hardware and/or software. For example, the operations performed by the estimation circuit 304 may be completed by a processor running estimation codes, but the present invention is not limited thereto. The DPD circuit 302 is electrically connected to the PA 304 and the estimation circuit 306. The estimation circuit 306 is also electrically connected to the PA 304.

The DPD circuit 302 receives an input signal u(n). The DPD circuit 302 performs DPD on the input signal u(n) based on a current DPD coefficient a^{k} to compensate for the nonlinearity of the PA 304. The PA 304 outputs an output signal y(n). The estimation circuit 306 receives the input signal u(n) and the output signal y(n) to calculate the DPD coefficient residual aᵣₑₛ^{k} at the current time point. That is, the DPD coefficient residual aᵣₑₛ^{k} is associated with the input signal u(n) received by the DPD circuit 302 and the output signal y(n) output by the PA 304. The estimation circuit 306 obtains the last DPD coefficient a^{k-1} at the last time point. The current DPD coefficient a^{k} is combined with the last DPD coefficient a^{k-1} and the DPD coefficient residual aᵣₑₛ^{k}. In some embodiments, the relationship between the DPD coefficient residual aᵣₑₛ^{k}, the input signal u(n), and the output signal y(n) is shown in the following equation 1.

$${a}_{res}^{k} = {( {A}_{{y}^{k}}^{H} {A}_{{y}^{k}} )}^{- 1} {A}_{{y}^{k}}^{H} u \qquad equation l$$

Matrix A_{y}_{^{k}} is a DPD basis function matrix composed of the output signal y(n). Matrix u is a matrix expression of the input signal u(n). Matrix A_{y}_{^{k}}^{H} is a transport matrix of matrix A_{y}_{^{k. Matrix (A}}_{y}_{^{k}}^{H}A_{y}_{^{k}})⁻¹ is an inverse matrix of matrix (A_{y}_{^{k}}^{H}A_{y}_{^{k).}}

In some embodiments, the DPD coefficient residual aᵣₑₛ^{k} and the last DPD coefficient a^{k-1} are expressed as polynomial matrices. The polynomial matrices, for example, may be expressed as following expression 2.

$$a 4 * {\vert u ( n ) \vert}^{5} + a 2 * {\vert u ( n ) \vert}^{3} + a 0 * \vert u ( n ) \vert \qquad expression 2$$

$${\vert u ( n ) \vert}^{2} * \vert u ( n - 1 ) \vert$$

$$\vert u ( n ) * u ( n - 2 ) \vert$$

Expression 2 shows a matrix having 3 taps. The first tap is related to the input signal at the current time point, for example, u(n). The second tap is related to the input signal at the current time point and the last time point, for example, u(n) and u(n−1). The third tap is related to the input signal at the current time point and the time point before the last time point, for example, u(n) and u(n−2). Constants a4, a2, and a0 are coefficients, for example, in the DPD coefficient residual aᵣₑₛ^{k}, to be calculated. In some embodiments, when the DPD coefficient residual aᵣₑₛ^{k} and the last DPD coefficient a^{k-1} are expressed as polynomial matrices, the estimation circuit 306 converts the DPD coefficient residual aᵣₑₛ^{k} and the last DPD coefficient a^{k-1} from the form of polynomial matrices to the form of lookup table (LUT) matrices based on the amplitudes of the input signal u(n) and the output signal y(n). In some embodiments, when the DPD coefficient residual aᵣₑₛ^{k} and the last DPD coefficient a^{k-1} are expressed as polynomial matrices, the estimation circuit 306 converts the current DPD coefficient a^{k} from the form of a LUT matrix to the form of a polynomial matrix after performing the truncation.

The lookup table matrices, for example, may be expressed as following expression 3.

$$h ( 0 , \vert u \vert = \frac{1}{16} ) h ( 0 , \vert u \vert = \frac{2}{16} ) … h ( 0 , \vert u \vert = \frac{16}{16} ) \qquad expression 3$$

$$h ( 1 , \vert u \vert = \frac{1}{16} ) h ( 1 , \vert u \vert = \frac{2}{16} ) … h ( 1 , \vert u \vert = \frac{16}{16} )$$

$$h ( 2 , \vert u \vert = \frac{1}{16} ) h ( 2 , \vert u \vert = \frac{2}{16} ) … h ( 2 , \vert u \vert = \frac{16}{16} )$$

It is assumed that the amplitudes of the input signal u(n) is divided into 16 equal parts. By substituting the amplitudes into the polynomial matrices like expression 2, the lookup table matrices like expression 3 can be obtained. The matrix h also have 3 taps, but have 16 elements in one row. In some embodiments, when the DPD coefficient residual aᵣₑₛ^{k} and the last DPD coefficient a^{k-1} are expressed as 3×3 polynomial matrices, the estimation circuit 306 converts the DPD coefficient residual aᵣₑₛ^{k} and the last DPD coefficient a^{k-1} into 3×16 LUT matrices, but the present invention is not limited thereto.

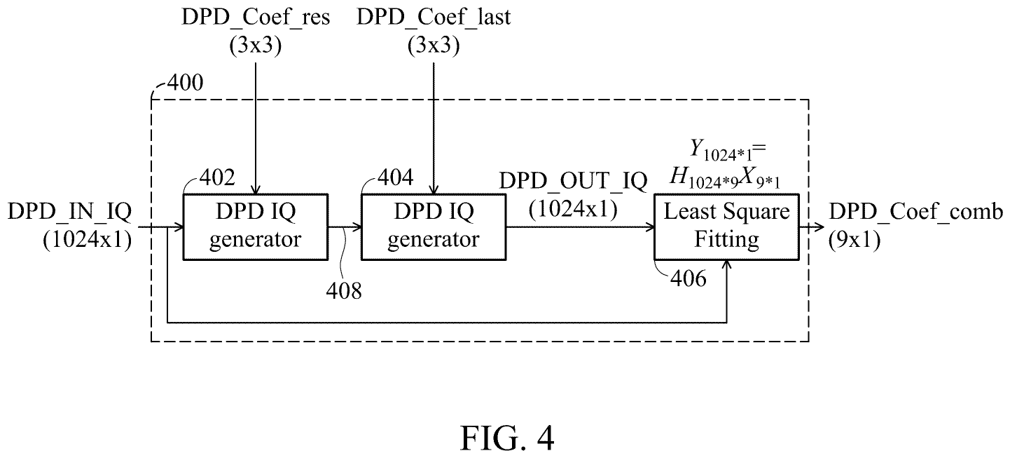

FIG. 4 shows a detail flow chart of operations of an estimation circuit 400 in the prior art. As shown in FIG. 4, the estimation circuit 400 in the prior art includes a DPD IQ generator 402, a DPD IQ generator 404, and a function block 406 of least square fitting. The DPD IQ generator 402 receives an input signal DPD_IN_IQ and the DPD coefficient residual DPD_Coef_res which is calculated before. The input signal DPD_IN_IQ is a polynomial matrix having a size of 1024×1. The DPD coefficient residual DPD_Coef_res is a polynomial matrix having a size of 3×3. The DPD IQ generator 402 generates an intermediate signal 408 based on the input signal DPD_IN_IQ and the DPD coefficient residual DPD_Coef_res. After that, the DPD IQ generator 404 receives the intermediate signal 408 and the last DPD coefficient DPD_Coef_last. The DPD IQ generator 404 outputs a signal DPD_OUT_IQ having a size of 1024×1 based on the intermediate signal 408 and the last DPD coefficient DPD_Coef_last. The function block 406 of least square fitting calculates a current DPD coefficient DPD_Coef_comb based on the following equation 4.

$${Y}_{1024 * 1} = {H}_{1024 * 9} {X}_{9 * 1} \qquad equation 4$$

Matrix Y_{1024*1} is a polynomial matrix representing the signal DPD_OUT_IQ. Matrix X_{9*1} is a polynomial matrix representing the current DPD coefficient DPD_Coef_comb. Matrix H_{1024*9} is a transfer function between Matrix Y_{1024*1} and Matrix X_{9*1}. Matrix X_{9*1} having the size of 9×1 can then be calculated by least square fitting. Computation cost to calculate polynomial matrix X_{9*1} based on equation 4 is high.

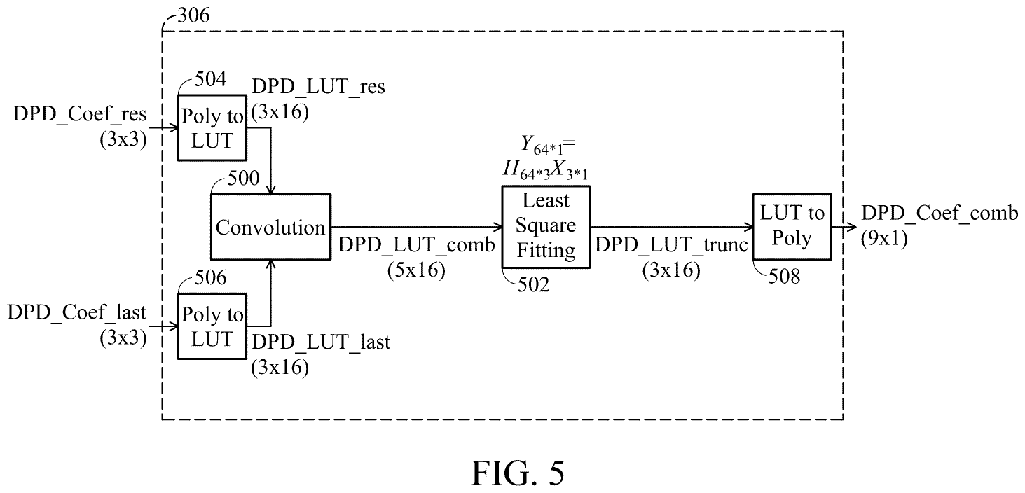

FIG. 5 shows a detail flow chart of operations of an estimation circuit 306 in FIG. 3 in accordance with some embodiments of the present invention. As shown in FIG. 5, the estimation circuit 306 in FIG. 3 includes a function block 504 of converting Poly to LUT, a function block 506 of converting Poly to LUT, a function block 500 of a convolution, a function block 502 of least square fitting, and a function block 508 of converting LUT to Poly. The estimation circuit 306 receives the DPD coefficient residual DPD_Coef_res that has been calculated and obtains the last DPD coefficient DPD_Coef_last. The DPD coefficient residual DPD_Coef_res and the last DPD coefficient DPD_Coef_last are polynomial matrices having a size of 3×3. The estimation circuit 306 performs function block 504 to convert the DPD coefficient residual DPD_Coef_res from the form of the polynomial matrix to the form of lookup table (LUT) matrix based on the amplitudes of the input signal u(n) and the output signal y(n). The DPD coefficient residual DPD_LUT_res having a size of 3×16 is obtained. Similarly, The estimation circuit 306 performs function block 506 to convert the last DPD coefficient DPD_Coef_last from the form of the polynomial matrix to a form of LUT matrix based on the amplitudes of the input signal u(n) and the output signal y(n). The last DPD coefficient DPD_LUT_last having a size of 3×16 is obtained.

After that, the estimation circuit 306 performs the convolution (function block 500) between the DPD coefficient residual DPD_LUT_res and the last DPD coefficient DPD_LUT_last to obtain an intermediate coefficient DPD_LUT_comb having a size of 5×16. Next, the estimation circuit 306 performs a truncation (function block 502) on the intermediate coefficient DPD_LUT_comb to obtain a current DPD coefficient DPD_LUT_trunc having a size of 3×16 based on the following equation 5.

$${Y}_{64 * 1} = {H}_{64 * 3} {X}_{3 * 1} \qquad equation 5$$

In detail, the estimation circuit 306 performs a Fast Fourier Transform (FFT) on the intermediate coefficient DPD_LUT_comb to obtain a matrix Y_{64*1}. Then, the estimation circuit 306 performs least square fitting (function block 502) on the intermediate coefficient DPD_LUT_comb to obtain the current DPD coefficient DPD_LUT_trunc having the size of 3×16. Matrix H_{64*3} is a transfer function between Matrix Y_{64*1} and Matrix X_{3*1}. Matrix X_{3*1} having the size of 3×1 can then be calculated by least square fitting. Matrix X_{3*1} is a LUT matrix representing the current DPD coefficient DPD_LUT_trunc in an FFT form. Computation cost to calculate LUT matrix X_{3*1} based on equation 5 is lower than that to calculate polynomial matrix X_{9*1} based on equation 4.

After the current DPD coefficient DPD_LUT_trunc having the size of 3×16 is calculated, the estimation circuit 306 performs function block 508 to convert the current DPD coefficient DPD_LUT_trunc from a form of the LUT matrix to a form of the polynomial matrix. Therefore, a current DPD coefficient DPD_Coef_comb having a size of 9×1 is generated. The current DPD coefficient DPD_Coef_comb is sent back to the DPD circuit 302 in FIG. 3. The DPD circuit 302 in FIG. 3 performs DPD based on the current DPD coefficient DPD_Coef_comb to compensate for the nonlinearity of the PA 304.

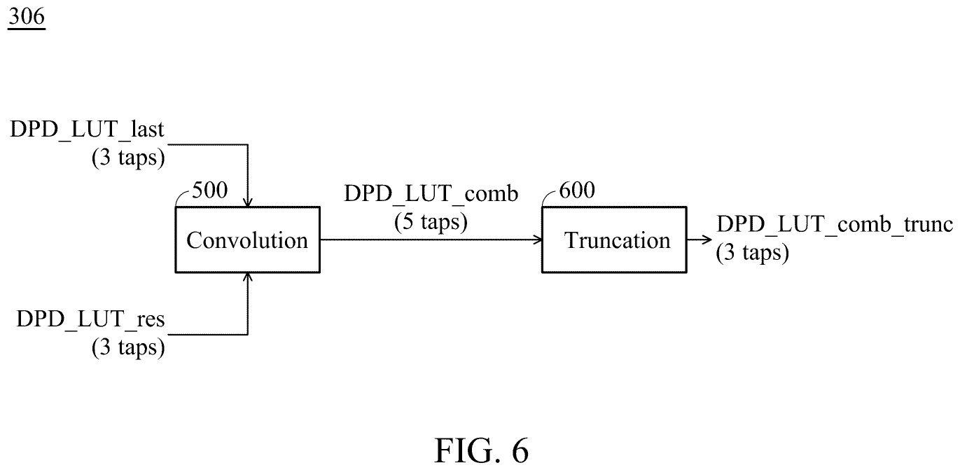

FIG. 6 shows a detail flow chart of operations of the estimation circuit 306 in FIG. 3 in accordance with some embodiments of the present invention. As shown in FIG. 6, the estimation circuit 306 includes a function block 500 of a convolution and a function block 600 of a truncation. The estimation circuit 306 receives the DPD coefficient residual DPD_LUT_res that has been calculated and obtains the last DPD coefficient DPD_LUT_last. The DPD coefficient residual DPD_LUT_res and the last DPD coefficient DPD_LUT_last are LUT matrices having 3 taps. The estimation circuit 306 performs the convolution (function block 500) between the DPD coefficient residual DPD_LUT_res and the last DPD coefficient DPD_LUT_last to obtain an intermediate coefficient DPD_LUT_comb having 5 taps. Compared with FIG. 5, since the DPD coefficient residual DPD_LUT_res and the last DPD coefficient DPD_LUT_last already are LUT matrices, function blocks 504, 506, and 508 are not necessary in FIG. 6.

Next, the estimation circuit 306 performs a truncation (function block 600) on the intermediate coefficient DPD_LUT_comb based on the following equation 6 to obtain a current DPD coefficient DPD_LUT_comb_trunc having 3 taps.

DPD_LUT_comb_trunc=(H_{FFT}^{H}H_{FFT})⁻¹H_{FFT}^{H}DPD_LUT_comb . . . equation 6

Matrix H_{FFT} is an FFT transfer function. Matrix (H_{FFT}^{H}H_{FFT})⁻¹ is an inverse matrix of matrix (H_{FFT}^{H}_{FFT}^{H}). Matrix H_{FFT}^{H} is a transport matrix of matrix H_{FFT}.

The operations of function block 600 in FIG. 6 may be the same as the operations of function block 502. The current DPD coefficient DPD_LUT_comb_trunc is sent back to the DPD circuit 302 in FIG. 3. The DPD circuit 302 in FIG. 3 performs DPD based on the current DPD coefficient DPD_LUT_comb_trunc to compensate for the nonlinearity of the PA 304.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for digital pre-distortion (DPD), applied to an electronic device having a DPD circuit and a power amplifier (PA), wherein the DPD circuit is electrically connected to the PA, the method comprising:
calculating a DPD coefficient residual at a current time point; wherein the DPD coefficient residual is associated with an input signal received by the DPD circuit and an output signal output by the PA;
obtaining a last DPD coefficient at a last time point;
performing a convolution between the DPD coefficient residual and the last DPD coefficient to obtain an intermediate coefficient;
performing a truncation on the intermediate coefficient to obtain a current DPD coefficient, and
performing DPD based on the current DPD coefficient to compensate for nonlinearity of the PA.

2. The method as claimed in claim 1, wherein the DPD coefficient residual and the last DPD coefficient are expressed as polynomial matrices.

3. The method as claimed in claim 1, wherein the DPD coefficient residual and the last DPD coefficient are expressed as lookup table (LUT) matrices.

4. The method as claimed in claim 2, further comprising:
converting the DPD coefficient residual and the last DPD coefficient from a form of the polynomial matrices to a form of lookup table (LUT) matrices based on amplitudes of the input signal and the output signal before performing the convolution.

5. The method as claimed in claim 4, wherein the intermediate coefficient and the current DPD coefficient are expressed as LUT matrices.

6. The method as claimed in claim 4, wherein the polynomial matrices are converted to the LUT matrices by substituting the amplitudes of the input signal and the output signal into the polynomial matrices.

7. The method as claimed in claim 5, further comprising:
converting the current DPD coefficient from a form of a LUT matrix to a form of a polynomial matrix after performing truncation.

8. The method as claimed in claim 5, wherein the step of performing truncation on the intermediate coefficient to obtain the current DPD coefficient comprises:
performing a Fast Fourier Transform (FFT) on the intermediate coefficient; and
performing a least square fitting on the intermediate coefficient to obtain the current DPD coefficient.

9. The method as claimed in claim 1, wherein the input signal and the output signal are In-phase Quadrature (IQ) signals.

10. The method as claimed in claim 7, wherein computation cost of the LUT matrix is less than that of the polynomial matrix.

11. An electronic device, comprising:
a digital pre-distortion (DPD) circuit, configured to receive an input signal;
a power amplifier (PA), electrically connected to the DPD circuit, configured to output an output signal; and
an estimation circuit, electrically connected to the DPD circuit and the PA, configured to:
calculate the DPD coefficient residual at the current time point; wherein the DPD coefficient residual is associated with the input signal received by the DPD circuit and the output signal output by the PA;
obtain the last DPD coefficient at the last time point;
perform a convolution between the DPD coefficient residual and the last DPD coefficient to obtain an intermediate coefficient, and
perform a truncation on the intermediate coefficient to obtain a current DPD coefficient;
wherein the DPD circuit performs DPD based on the current DPD coefficient to compensate for the nonlinearity of the PA.

12. The electronic device as claimed in claim 11, wherein the DPD coefficient residual and the last DPD coefficient are expressed as polynomial matrices.

13. The electronic device as claimed in claim 11, wherein the DPD coefficient residual and the last DPD coefficient are expressed as lookup table (LUT) matrices.

14. The electronic device as claimed in claim 12, wherein the estimation circuit converts the DPD coefficient residual and the last DPD coefficient from the form of polynomial matrices to the form of lookup table (LUT) matrices based on the amplitudes of the input signal and the output signal before performing the convolution.

15. The electronic device as claimed in claim 14, wherein the intermediate coefficient and the current DPD coefficient are expressed as LUT matrices.

16. The electronic device as claimed in claim 14, wherein the polynomial matrices are converted to the LUT matrices by substituting the amplitudes of the input signal and the output signal into the polynomial matrices.

17. The electronic device as claimed in claim 15, wherein the estimation circuit converts the current DPD coefficient from the form of a LUT matrix to the form of a polynomial matrix after performing the truncation.

18. The electronic device as claimed in claim 15, wherein the estimation circuit performs a Fast Fourier Transform (FFT) on the intermediate coefficient, and performs least square fitting on the intermediate coefficient to obtain the current DPD coefficient.

19. The electronic device as claimed in claim 11, wherein the input signal and the output signal are In-phase Quadrature (IQ) signals.

20. The electronic device as claimed in claim 17, wherein computation cost of the LUT matrix is less than that of the polynomial matrix.
